(19) United States
(12) Patent Application Publication
(10) Pub. No.: US 2016/0293625 A1
(43) Pub. Date: Oct. 6, 2016

(54) Three Dimensional Semiconductor Memory Devices and Methods of Fabricating the Same

(71) Applicants: Joo-Heon Kang, Seoul (KR); Junho CHA, Seongnam-si (KR); Chung-II HYUN, Kwaseong-si (KR)

(72) Inventors: Joo-Heon Kang, Seoul (KR); Junho CHA, Seongnam-si (KR); Chung-II HYUN, Kwaseong-si (KR)

(21) Appl. No.: 15/055,818

(22) Filed: Feb. 29, 2016

(30) Foreign Application Priority Data
Mar. 31, 2015 (KR) 10-2015-0045675
May 22, 2015 (KR) 10-2015-0072028

(51) Int. Cl. H01L 27/115; H01L 23/522; H01L 23/528

(52) U.S. Cl. CPC H01L 27/11582; H01L 27/11568; H01L 27/11573; H01L 23/528; H01L 23/5226

(57) ABSTRACT

A semiconductor memory device is provided including a substrate; a stack structure including gate electrodes vertically stacked on the substrate; a vertical channel part penetrating the gate electrodes; a dopant region provided in the substrate at a side of the stack structure; a common source plug on the substrate and electrically connected to the dopant region; and cell contact plugs connected to the gate electrodes, respectively. A top surface of the common source plug is at a different level from top surfaces of the cell contact plugs.

### CROSS-REFERENCE TO RELATED APPLICATION

This U.S. non-provisional patent application claims priority under 35 U.S.C. §119 to Korean Patent Application Nos. 10-2015-0045675 and 10-2015-0072028, filed on Mar. 31, 2015 and May 22, 2015, respectively, in the Korean Intellectual Property Office, the disclosures of which are hereby incorporated herein by reference as if set forth in their entireties.

### FIELD

The inventive concept relate generally to semiconductor devices and, more particularly, to semiconductor memory devices and methods of fabricating the same.

### BACKGROUND

Semiconductor devices have been highly integrated to provide high performance and decrease costs. In particular, the integration density of semiconductor memory devices may directly affect the costs of the semiconductor memory devices. An integration density of a conventional two-dimensional (2D) memory device may be mainly determined by an area that a unit memory cell occupies, so it may be greatly affected by a technique of forming fine patterns. However, since extremely high-priced apparatus are needed to form fine patterns, the integration density of 2D memory devices continues to increase, but is still limited.

To overcome these limitations, a 3D semiconductor memory device including memory cells three-dimensionally arranged has been developed.

### SUMMARY

Some embodiments of the present inventive concept provide a semiconductor memory device including a substrate; a stack structure including gate electrodes vertically stacked on the substrate; a vertical channel part penetrating the gate electrodes; a dopant region provided in the substrate at a side of the stack structure; a common source plug disposed on the substrate and electrically connected to the dopant region; and cell contact plugs connected to the gate electrodes, respectively. A top surface of the common source plug may be disposed at a different level from top surfaces of the cell contact plugs.

In further embodiments, the top surfaces of the cell contact plugs may be at a higher level than the top surface of the common source plug.

In still further embodiments, the semiconductor memory device may further include a first separation insulating layer and a second separation insulating layer sequentially stacked on the stack structure. The common source plug may extend upward to penetrate the first separation insulating layer, and the top surface of the common source plug may be disposed at the substantially same level as a top surface of the first separation insulating layer. The cell contact plugs may extend upward to penetrate the first and second separation insulating layers, and the top surfaces of the cell contact plugs may be disposed at the substantially same level as a top surface of the second separation insulating layer.

In some embodiments, the second separation insulating layer may extend onto the common source plug to cover the top surface of the common source plug.

In further embodiments, a top surface of the vertical channel part may be lower than the top surface of the common source plug and the top surfaces of the cell contact plugs.

In still further embodiments, the substrate may include a cell array region in which the vertical channel part is disposed, a contact region in which the cell contact plugs are disposed, and a peripheral circuit region. In these embodiments, the semiconductor memory device may further include a peripheral gate pattern disposed on the substrate of the peripheral circuit region, a peripheral dopant region provided in the substrate at a side of the peripheral gate pattern, and peripheral contact plugs disposed on the substrate of the peripheral circuit region. The peripheral contact plugs may be electrically connected to the peripheral gate pattern and the peripheral dopant region.

In some embodiments, top surfaces of the peripheral contact plugs may be disposed at the substantially same level as the top surfaces of the cell contact plugs.

Further embodiments of the present inventive concept provide a semiconductor memory device including a substrate comprising a cell array region and a contact region; a stack structure including gate electrodes vertically stacked on the substrate; a vertical channel part penetrating the gate electrodes on the substrate of the cell array region; a dopant region provided in the substrate at a side of the stack structure; a common source plug disposed on the substrate and electrically connected to the dopant region; and cell contact plugs respectively connected to the gate electrodes on the substrate of the contact region. A top surface of the vertical channel part, a top surface of the common source plug, and a top surface of each of the cell contact plugs may be disposed at levels different from each other.

In still further embodiments, the top surface of the vertical channel part may be disposed at a lower level than the top surface of the common source plug.

In some embodiments, the top surface of the vertical channel part may be at a lower level than the top surface of the common source plug, and the top surface of the common source plug may be at a lower level than the top surfaces of the cell contact plugs.

Further embodiments of the present inventive concept provided a three-dimensional semiconductor memory device including a stack structure including gate electrodes vertically stacked on a substrate; a vertical channel part penetrating the gate electrodes on the substrate in a cell array region thereof; a dopant region in the substrate at a side of the stack structure; a common source plug on the substrate, the common source plug electrically connected to the dopant region; cell contact plugs respectively connected to the gate electrodes on the substrate in a contact region thereof; a peripheral gate pattern on the substrate in a peripheral circuit region thereof; a peripheral dopant region in the substrate at a side of the peripheral gate pattern; and peripheral contact plugs on the substrate of the peripheral circuit region. A top surface of the vertical channel part, a top surface of the common source plug, a top surface of each of the cell contact plugs and peripheral contact plugs are at levels different from each other.

In still further embodiments, the top surface of the vertical channel part may be at a lower level than the top surface of the common source plug.

In some embodiments, the top surface of the vertical channel part may be at a lower level than the top surfaces of the cell contact plugs.

In further embodiments, the top surface of the vertical channel part may be at a lower level than the top surface of the common source plug. The top surface of the common source plug may be at a lower level than the top surfaces of the cell contact plugs.

In still further embodiments, the peripheral contact plugs may be electrically connected to the peripheral gate pattern and the peripheral dopant region. Top surfaces of the peripheral contact plugs may be disposed at substantially the same level as the top surfaces of the cell contact plugs.

### BRIEF DESCRIPTION OF THE DRAWINGS

The inventive concept will become more apparent in view of the attached drawings and accompanying detailed description.

FIG. 1 is a plan view illustrating a semiconductor memory device according to some embodiments of the present inventive concept.

FIG. 2 is a cross-section taken along lines I-I′ and II-II′ of FIG. 1 illustrating a semiconductor memory device according to some embodiments of the present inventive concept.

FIG. 3 is a cross-section taken along lines I-I′ and II-II′ of FIG. 1 illustrating a semiconductor memory device according to some embodiments of the inventive concept.

FIGS. 4A to 4M are cross-sections taken along lines I-I′ and II-II′ of FIG. 1 illustrating processing steps in the fabrication of a semiconductor memory device according to some embodiments of the present inventive concept.

FIG. 5 is a schematic block diagram illustrating an example of an electronic system including a semiconductor memory device according to some embodiments of the present inventive concept.

FIG. 6 is a schematic block diagram illustrating an example of a memory system including a semiconductor memory device according to some embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described In particular with reference to the accompanying drawings. It should be noted, however, that the inventive concept are not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-section(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-section(s) illustrated herein provide support for a plurality of devices according to various embodiments described herein that extend along two different directions in a plan view and/or in three different directions in a perspective view. For example, when a single active region is illustrated in a cross-section of a device/structure, the device/structure may include a plurality of active regions and transistor structures (or memory cell structures, gate structures, etc., as appropriate to the case) thereon, as would be illustrated by a plan view of the device/structure.

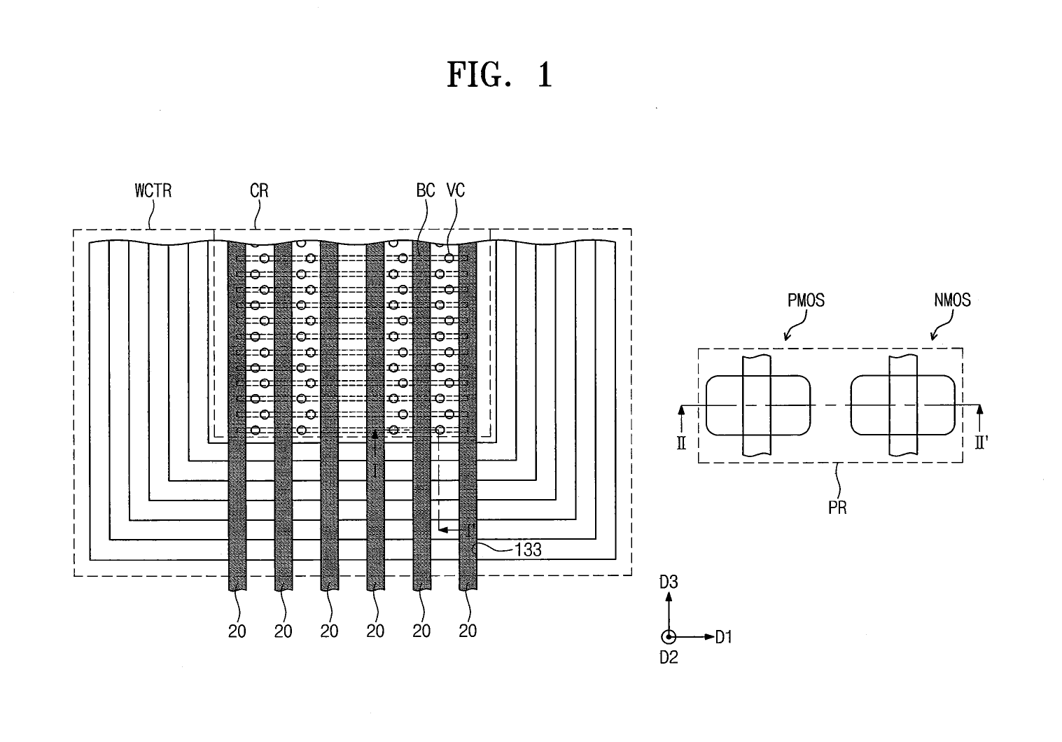

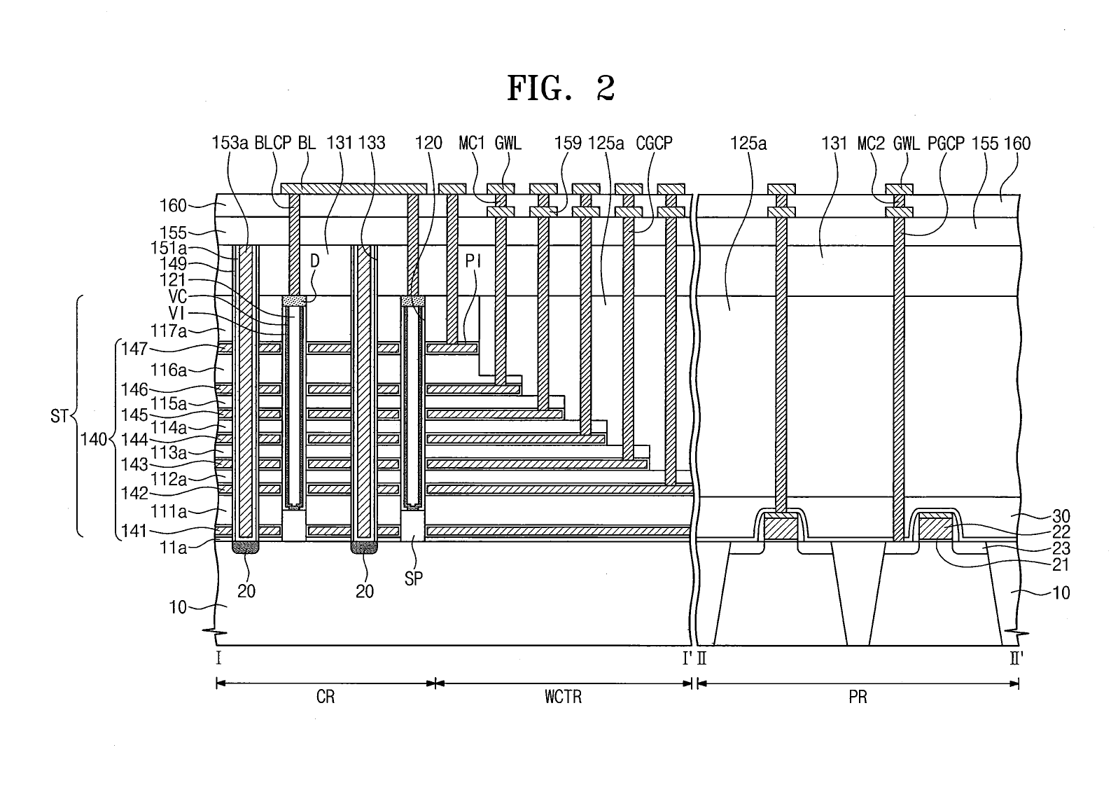

FIG. 1 is a plan view illustrating a semiconductor memory device according to some embodiments of the inventive concept. FIG. 2 is a cross-section taken along lines I-I′ and II-II′ of FIG. 1 illustrating a semiconductor memory device according to some embodiments of the inventive concept.

Referring to FIGS. 1 and 2, a stack structure ST may be on a substrate 10. The substrate 10 may include a cell array region CR and a contact region WCTR. The stack structure ST may be on the substrate 10 of the cell array region CR and the contact region WCTR. The stack structure ST may extend in one direction D3. The substrate 10 may be, for example, a silicon substrate, a silicon-germanium substrate, a germanium substrate, or a single-crystalline epitaxial layer grown on a single-crystalline silicon substrate.

The substrate 10 may further include a peripheral circuit region PR. Peripheral transistors may be on the substrate 10 of the peripheral circuit region PR. The peripheral transistors may include, for example, a P-type metal-oxide-semiconductor (PMOS) transistor and an N-type metal-oxide-semiconductor (NMOS) transistor. The PMOS transistor and the NMOS transistor may be respectively provided on active regions of the substrate 10, which are defined by a device isolation layer. The PMOS transistor and the NMOS transistor may be included in a word line driver, a sense amplifier, a row decoder, a column decoder, or a control circuit.

In some embodiments, each of the peripheral transistors may include a peripheral gate insulating pattern 21 and a peripheral gate pattern 22 which are sequentially stacked on the substrate 10 of the peripheral circuit region PR. The peripheral gate pattern 22 may be used as a gate electrode of each of the peripheral transistors constituting a peripheral circuit and may be formed of at least one of poly-silicon doped with dopants or a metal material. Peripheral dopant regions 23, which are used as source and drain regions of the peripheral transistor, may be provided in the active region at both sides of the peripheral gate pattern 22.

A peripheral insulating pattern 30 may be provided on the substrate 10 to cover the peripheral transistors. The peripheral insulating pattern 30 may be formed of a silicon oxide layer, and the peripheral circuits of the peripheral circuit region PR may be covered with the peripheral insulating pattern 30.

The stack structure ST disposed on the substrate 10 of the cell array region CR and the contact region WCTR may include insulating patterns 111a to 117a and gate electrodes 140. The insulating patterns 111a to 117a and the gate electrodes 140 may be alternately and repeatedly stacked in a second direction D2 perpendicular to a top surface of the substrate 10. A gate insulating pattern 111a may be disposed between the substrate 10 and the stack structure ST. The gate insulating pattern 11a may include, for example, a silicon oxide layer.

The gate electrodes 140 may be stacked in the second direction D2 and may extend in the one direction D3. Lengths of the gate electrodes 140 in the one direction D3 may be different from each other. For example, the lengths of the gate electrodes 140 may be sequentially decreased as a distance from the substrate is increased. In other words, the stacked gate electrodes 140 disposed on the substrate 10 of the contact region WCTR may have a stepped structure. Thus, end portions of the gate electrodes 140 may be exposed on the substrate 10 of the contact region WCTR.

The gate electrodes 140 may include a ground selection gate electrode 141, cell gate electrodes 142 to 146, and a string selection gate electrode 147. The ground selection gate electrode 141 may correspond to the lowermost one of the gate electrodes 140, and the string selection gate electrode 147 may correspond to the uppermost one of the gate electrodes 140. The cell gate electrodes 142 to 146 may be disposed between the ground selection gate electrode 141 and the string selection gate electrode 147. The gate electrodes 140 may include at least one of, for example, doped silicon, a metal such as tungsten, copper, or aluminum, a conductive metal nitride such as titanium nitride or tantalum nitride, or a transition metal such as titanium or tantalum.

Each of the insulating patterns 111a to 117a may be disposed between the gate electrodes 140 vertically adjacent to each other. The insulating patterns 111a to 117a may be stacked in the second direction D2 and may extend in the one direction D3. Lengths of the insulating patterns 111a to 117a in the one direction D3 may be different from each other. For example, the lengths of the insulating patterns 111a to 117a may be sequentially decreased as a distance from the substrate 10 is increased. Each of the insulating patterns 111a to 117a may have the same length as the gate electrode 140 disposed immediately below each of the insulating patterns 111a to 117a. For example, the lowermost insulating pattern 111a may have the same length as the lowermost gate electrode 141 in the one direction D3. Thus, the insulating patterns 111a to 117a may cover the exposed end portions of the gate electrodes 140 on the substrate 10 of the contact region WCTR, respectively.

An interlayer insulating pattern 125a may be disposed on the substrate 10 of the contact region WCTR and the peripheral circuit region PR. The interlayer insulating pattern 125a may cover end portions of the insulating patterns 111a to 116a disposed on the substrate 10 of the contact region WCTR. Furthermore, the interlayer insulating pattern 125a may cover a top surface of the peripheral insulating pattern 30 of the peripheral circuit region PR. A top surface of the interlayer insulating pattern 125a may be disposed at substantially the same level as a top surface of the uppermost insulating pattern 117a. The interlayer insulating pattern 125a may include, for example, silicon oxide.

A vertical channel part VC may penetrate the stack structure ST disposed on the substrate 10 of the cell array region CR so as to be electrically connected to the substrate 10. A plurality of the vertical channel part VC may penetrate the stack structure ST and may be arranged in a zigzag form along the one direction D3. The vertical channel part VC may conformally cover a sidewall and a bottom surface of a channel hole 120 penetrating the stack structure ST. The vertical channel part VC may be formed of a single layer or a multi-layer. The vertical channel part VC may include at least one of, for example, a poly-crystalline silicon layer, an organic semiconductor layer, or a carbon nano structure.

A semiconductor pillar SP may be disposed between the substrate 10 and the vertical channel part VC. The semiconductor pillar SP may be grown from the substrate 10 by performing a selective epitaxial growth (SEG) process using the substrate 10, exposed through the channel hole 120, as a seed. For example, the semiconductor pillar SP may be formed of an intrinsic semiconductor or a semiconductor doped with P-type dopants.

A vertical insulating layer VI may be provided between the vertical channel part VC and the stack structure ST. The vertical insulating layer VI may conformally cover a portion of the bottom surface and the sidewall of the channel hole 120. The vertical insulating layer VI may be formed of a single layer or a multi-layer. For example, the vertical insulating layer VI may include at least one of thin layers such as a tunnel insulating layer, a trap insulating layer, and a blocking insulating layer, used as a memory element of a charge trap-type non-volatile memory transistor. For example, the vertical insulating layer VI may include at least one of a silicon oxide layer, a silicon nitride layer, or a silicon oxynitride layer. A horizontal insulating layer PI may be disposed between the vertical insulating layer VI and each of the gate electrodes 140. In particular, the horizontal insulating layer PI disposed on a sidewall of the gate electrode 140 may extend onto a top surface and a bottom surface of the gate electrode 140. The horizontal insulating layer PI may correspond to the blocking insulating layer of the charge trap-type non-volatile memory transistor. In these embodiments, the horizontal insulating layer PI may be a silicon oxide layer. Alternatively, the horizontal insulating layer PI may further include the trap insulating layer, or the trap insulating layer and the tunnel insulating layer. The vertical insulating layer VI and the horizontal insulating layer PI may constitute a data storage layer.

An insulating pillar 121 may be provided in the channel hole 120. The insulating pillar 121 may include an insulating material, for example, silicon oxide or silicon nitride. The insulating pillar 121 may be surrounded by the vertical channel part VC. The vertical channel part VC may further include conductive pad D. The conductive pad D may correspond to a top end portion of the vertical channel part VC. Top ends of the vertical insulating layer VI and the insulating pillar 121 may be in contact with a bottom surface of the conductive pad D. The conductive pad D may include a conductive material, or a semiconductor material doped with dopants of which a conductivity type is different from that of the vertical channel part VC. A top surface of the vertical channel part VC including the conductive pad D may be disposed at the substantially same level as the top surface of the uppermost insulating pattern 117a. In these embodiments, the top surface of the vertical channel part VC may be the top surface of the conductive pad D.

A dopant region 20 may be provided in the substrate 10 of the cell array region CR and the contact region WCTR. The dopant region 20 may extend along the one direction D3 in the substrate 10. The dopant region 20 may be a common source line. In these embodiments, a conductivity type of the dopant region 20 may be different from that of the substrate 10.

A first separation insulating layer 131 may be disposed on an entire top surface of the substrate 10. In particular, the first separation insulating layer 131 may cover the top surface of the uppermost insulating pattern 117a of the cell array region CR and may cover the interlayer insulating pattern 125a of the contact region WCTR and the peripheral circuit region PR. The first separation insulating layer 131 may cover the vertical channel part VC and may be in contact with the top surface of the conductive pad D. For example, the first separation insulating layer 131 may include an insulating material, for example, a silicon oxide layer.

A plurality of the stack structures ST may be provided on the substrate 10 of the cell array region CR and the contact region WCTR. A spacer 149, a barrier pattern 151a, and a common source plug 153a may be disposed in a common source trench 133 that exposes the dopant region 20 between the stack structures ST adjacent to each other. The common source trench 133 may extend upward to penetrate the first separation insulating layer 131 of the cell array region CR and the contact region WCTR. The common source trench 133 may have a linear shape extending in the one direction D3. The common source trench 133 may be provided in plurality on the substrate 10. The common source trenches 133 and the stack structures ST may be alternately arranged along a first direction D1 perpendicular to the one direction D3.

The spacer 149 may be disposed one each sidewall of the common source trench 133. For example, the spacer 149 may include a silicon oxide layer. The barrier pattern 151a may conformally cover a bottom surface of the common source trench 133 and sidewalls of the spacers 149 disposed on both sidewalls of the common source trench 133. In other words, the barrier pattern 151a may have a U-shaped cross-section. For example, the barrier pattern 151a may include a metal nitride such as titanium nitride or tantalum nitride.

The common source plug 153a may completely fill the common source trench 133 on the barrier pattern 151a. In other words, the common source plug 153a may be disposed between the stack structures ST adjacent to each other and may extend upward to penetrate the first separation insulating layer 131. Furthermore, the common source plug 153a may have a line shape extending in the one direction D3. The common source plugs 153a respectively disposed in the common source trenches 133 may be arranged along the first direction D1. Even though not shown in the drawings, the common source plug 153a may be electrically connected to a dummy vertical channel part penetrating the stack structure ST. For example, the common source plug 153a may include a metal, for example, tungsten, copper, or aluminum, or a transition metal, for example, titanium or tantalum.

A top surface of the common source plug 153a may be disposed at the substantially same level as the top surface of the first separation insulating layer 131. In other words, the first separation insulating layer 133 may correspond to the uppermost one of layers which the common source plugs 153a penetrate. The top surface of the common source plug 153a may be disposed at a higher level than the top surface of the vertical channel part VC.

A second separation insulating layer 155 may be provided on an entire top surface of the first separation insulating layer 131. The second separation insulating layer 155 may cover the top surfaces of the common source plug 153a, the barrier pattern 151a and the spacers 149. For example, the second separation insulating layer 155 may include an insulating material such as a silicon oxide layer, a silicon nitride layer, and/or a silicon oxynitride layer.

Cell contact plugs CGCP may penetrate the second separation insulating layer 155, the first separation insulating layer 131 and the interlayer insulating pattern 125a of the contact region WCTR so as to be in contact with the end portions of the gate electrodes 140, respectively. Peripheral contact plugs PGCP may penetrate the second separation insulating layer 155, the first separation insulating layer 131 and the interlayer insulating pattern 125a of the peripheral circuit region PR so as to be in contact with the peripheral gate pattern 22 and the peripheral dopant region 23, respectively. The cell contact plugs CGCP and the peripheral contact plugs PGCP may include a conductive material, for example, tungsten (W), copper (Cu), or aluminum (Al).

Top surfaces of the cell contact plugs CGCP and top surfaces of the peripheral contact plugs PGCP may be disposed at the substantially same level as a top surface of the second separation insulating layer 155. Furthermore, the top surfaces of the cell contact plugs CGCP and the top surfaces of the peripheral contact plugs PGCP may be disposed at a higher level than the top surface of the common source plug 153a. In other words, the top surface of the vertical channel part VC may be lower than the top surface of the common source plug 153a, and the top surface of the common source plug 153a may be lower than the top surfaces of the cell and peripheral contact plugs CGCP and PGCP.

Contact pads 159 may be disposed on the second separation insulating layer 155 so as to be in contact with the cell contact plugs CGCP and the peripheral contact plugs PGCP, respectively. An additional separation insulating layer 160 covering the contact pads 159 may be disposed on an entire top surface of the second separation insulating layer 155. A bit line contact plug BLCP may penetrate the first, second and additional separation insulating layers 131, 155 and 160 of the cell array region CR so as to be in contact with the conductive pad D. A bit line BL may be disposed on the additional separation insulating layer 160 so as to be connected to the bit line contact plug BLCP. A plurality of the bit lines BL may extend in the first direction D1 to intersect the stack structures ST and may be arranged in the one direction D3.

First contacts MC1 may penetrate the additional separation insulating layer 160 of the contact region WCTR, and second contacts MC2 may penetrate the additional separation insulating layer 160 of the peripheral circuit region PR. Global word lines GWL may be disposed on the additional separation insulating layer 160 so as to be connected to the first contacts MC1 and the second contacts MC2.

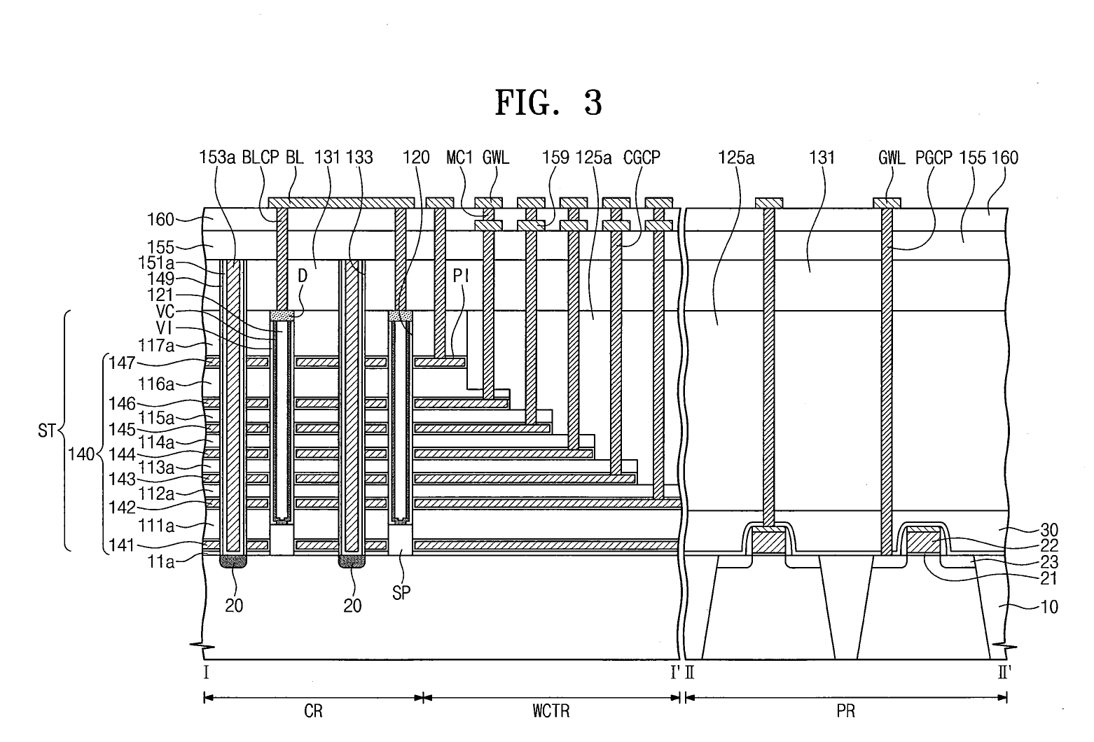

FIG. 3 is a cross-section taken along lines I-I′ and II-II′ of FIG. 1 illustrating a semiconductor memory device according to some embodiments of the inventive concept. Referring to FIGS. 2 and 3, the top surface of the vertical channel part VC may be lower than the top surface of the common source plug 153a which penetrates the first separation insulating layer 131 of the cell array region CR and extends downward between the stack structures ST so as to be connected to the dopant region 20 corresponding to the common source line. Cell contact plugs CGCP may penetrate the second and first separation insulating layers 155 and 131 and the interlayer insulating pattern 125a of the contact region WCTR so as to be connected to the gate electrodes 140. The top surfaces of the cell contact plugs CGCP may be higher than the top surface of the common source plug 153a. Peripheral contact plugs PGCP may penetrate the additional, second and first separation insulating layers 160, 155 and 131 and the interlayer insulating pattern 125a of the peripheral circuit region PR so as to be connected to the peripheral gate pattern 22 and the peripheral dopant region 23, respectively. The top surfaces of the peripheral contact plugs PGCP may be higher than the top surfaces of the cell contact plugs CGCP. In other words, an upper portion of the vertical channel part VC may be disposed at a lower level than an upper portion of the common source plug 153a, and the upper portion of the common source plug 153a may be disposed at a lower level than upper portions of the cell contact plugs CGCP and upper portion of the peripheral contact plugs PGCP. Furthermore, the upper portions of the cell contact plugs CGCP may be disposed at a lower level than the upper portions of the peripheral contact plugs PGCP.

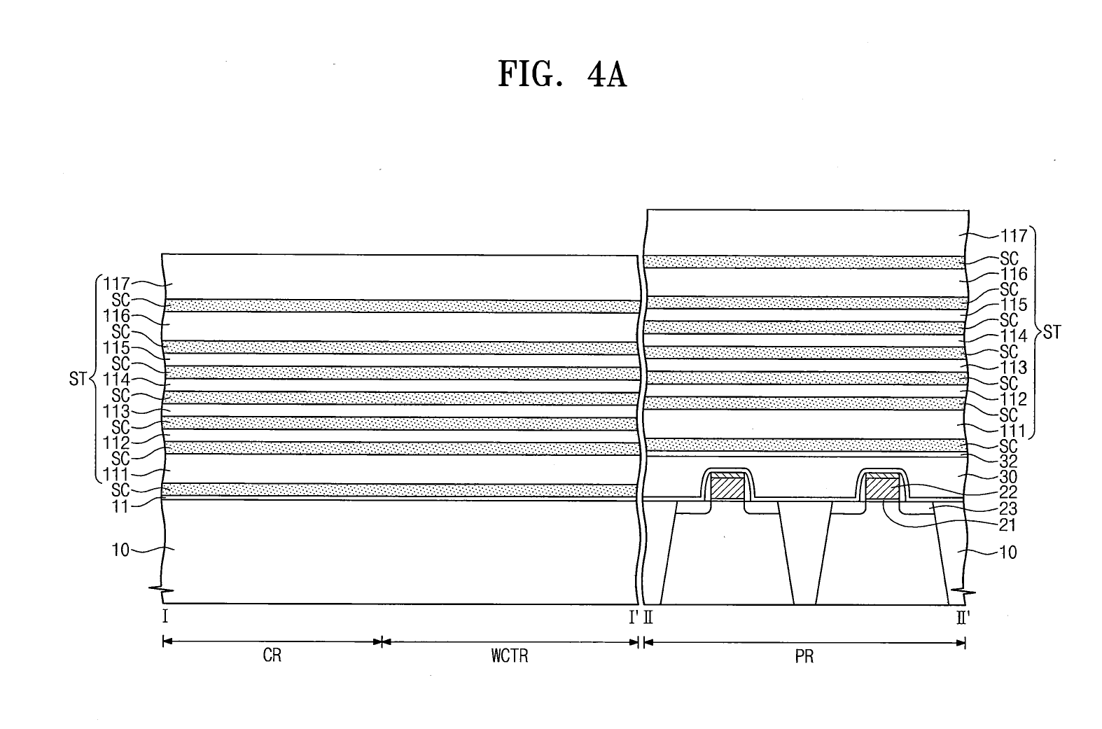

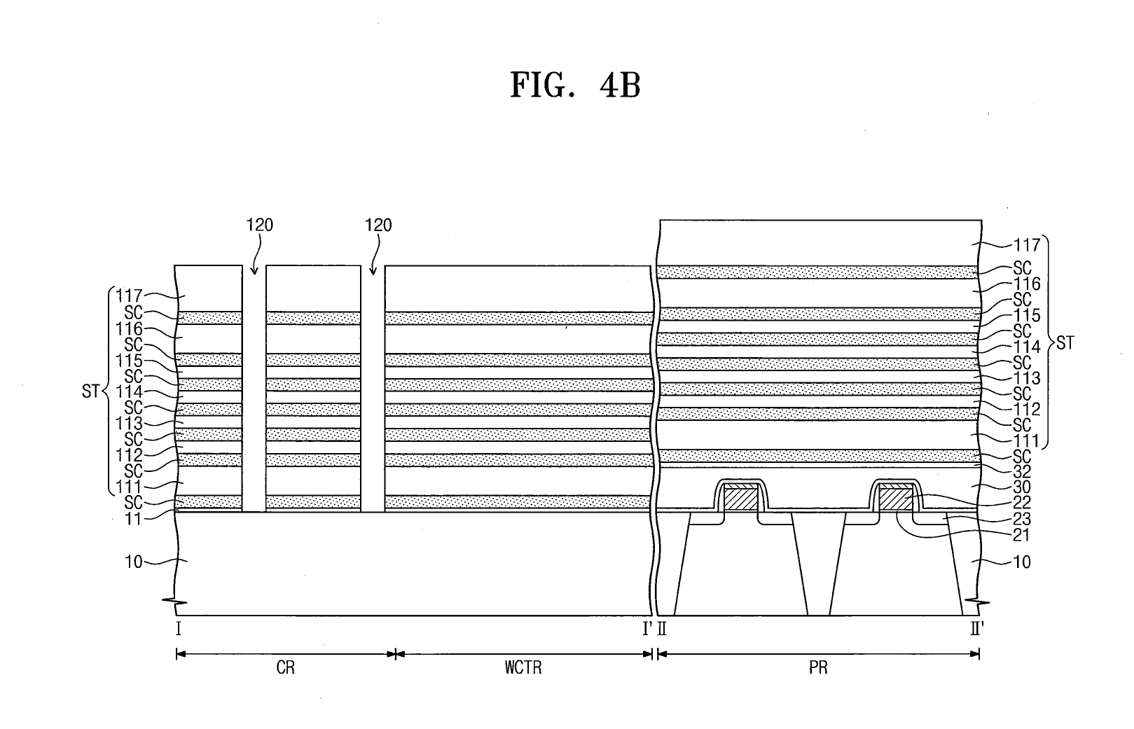

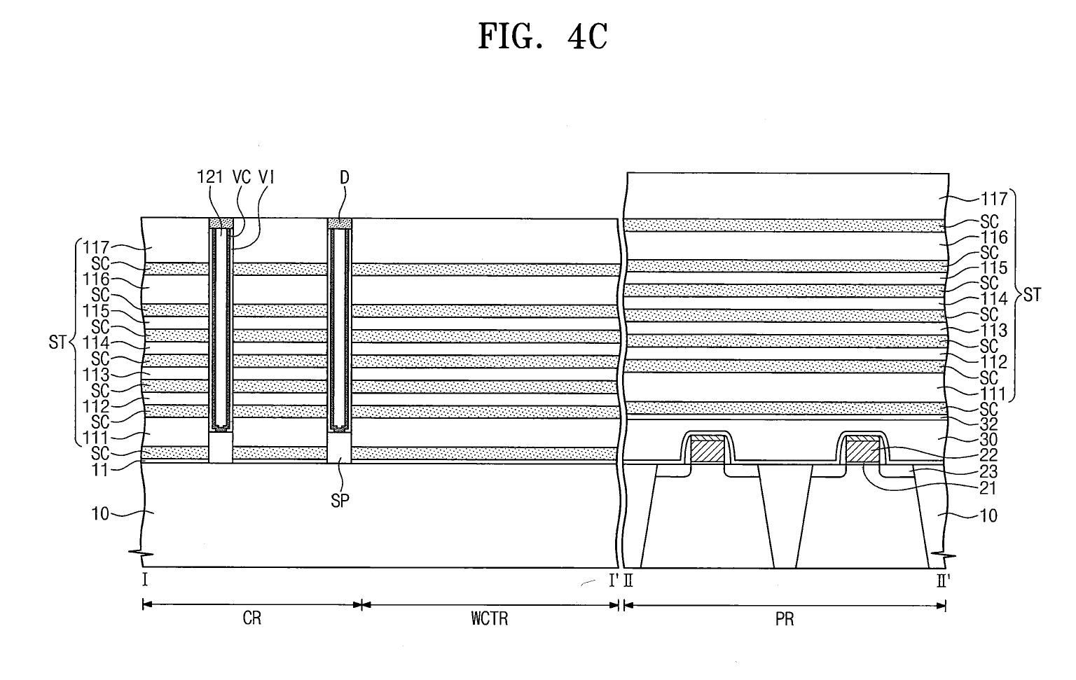

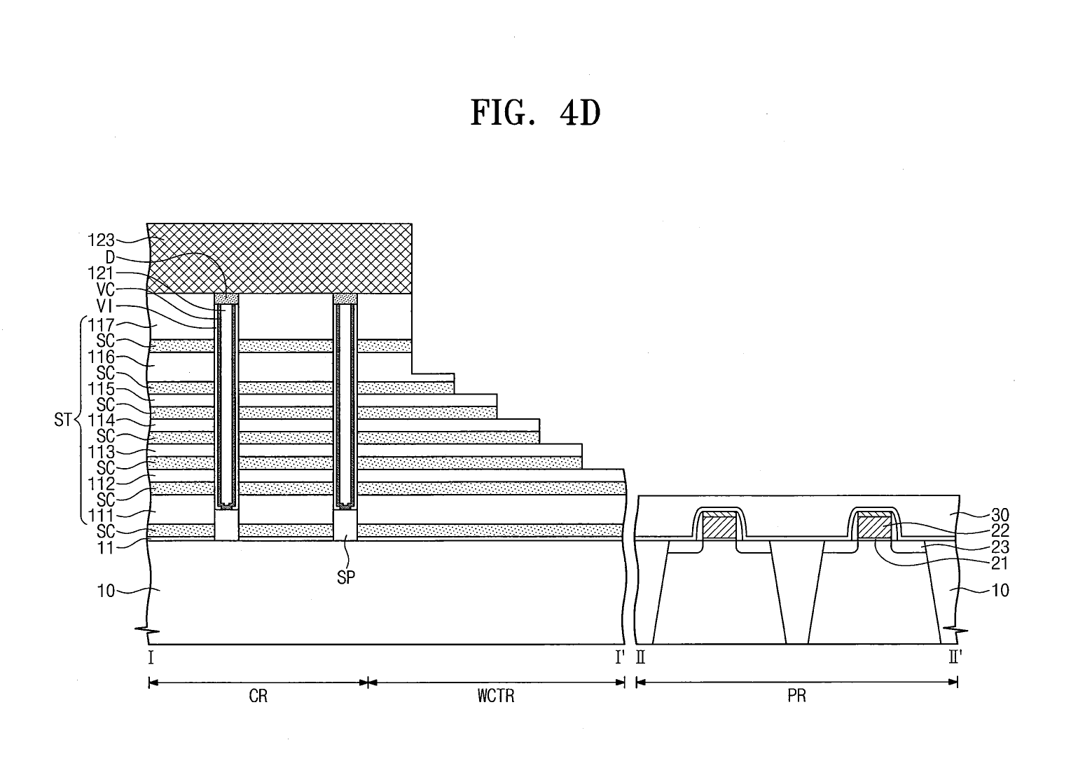

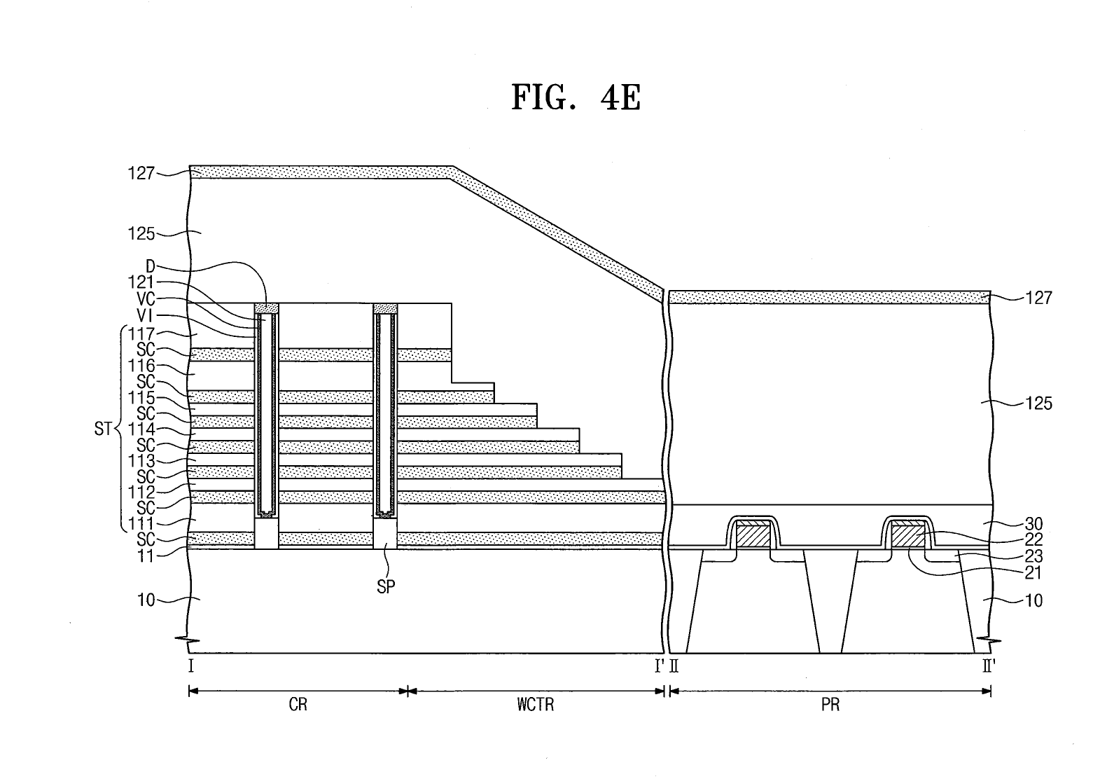

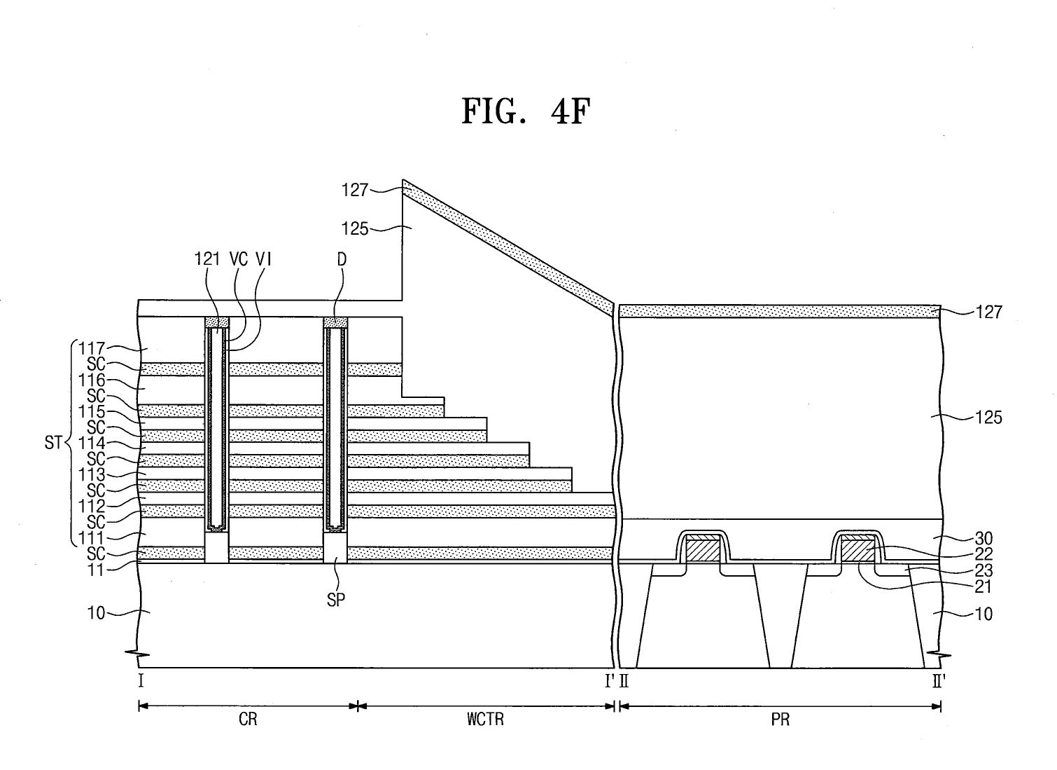

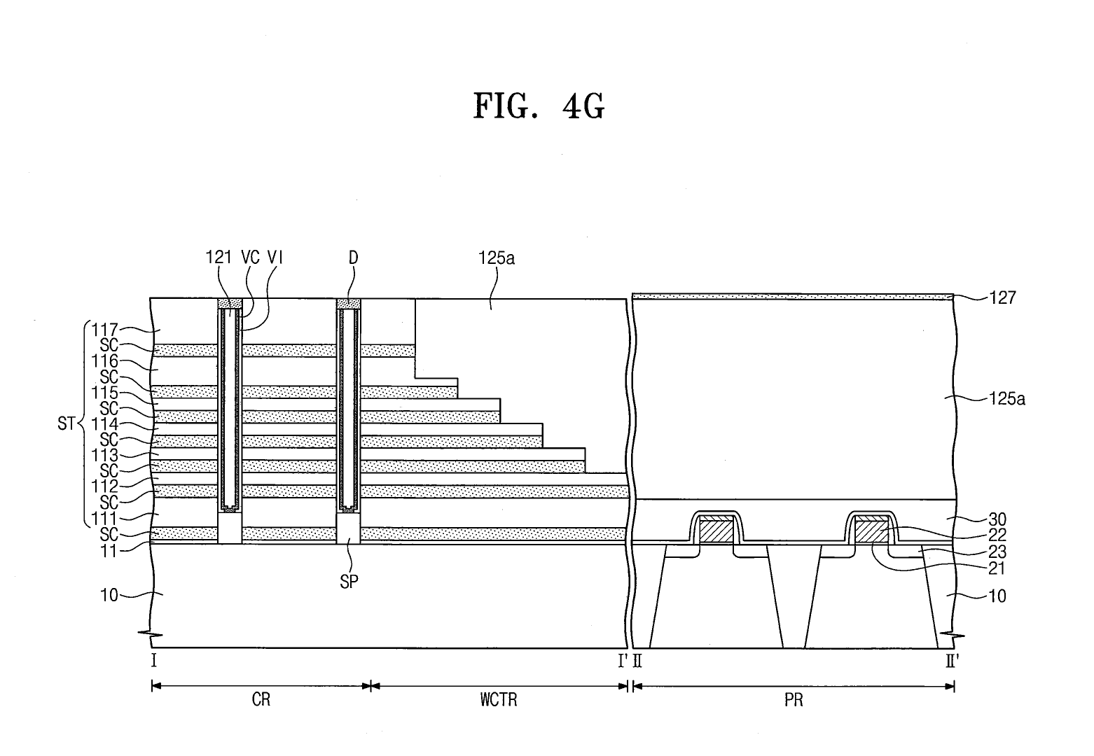

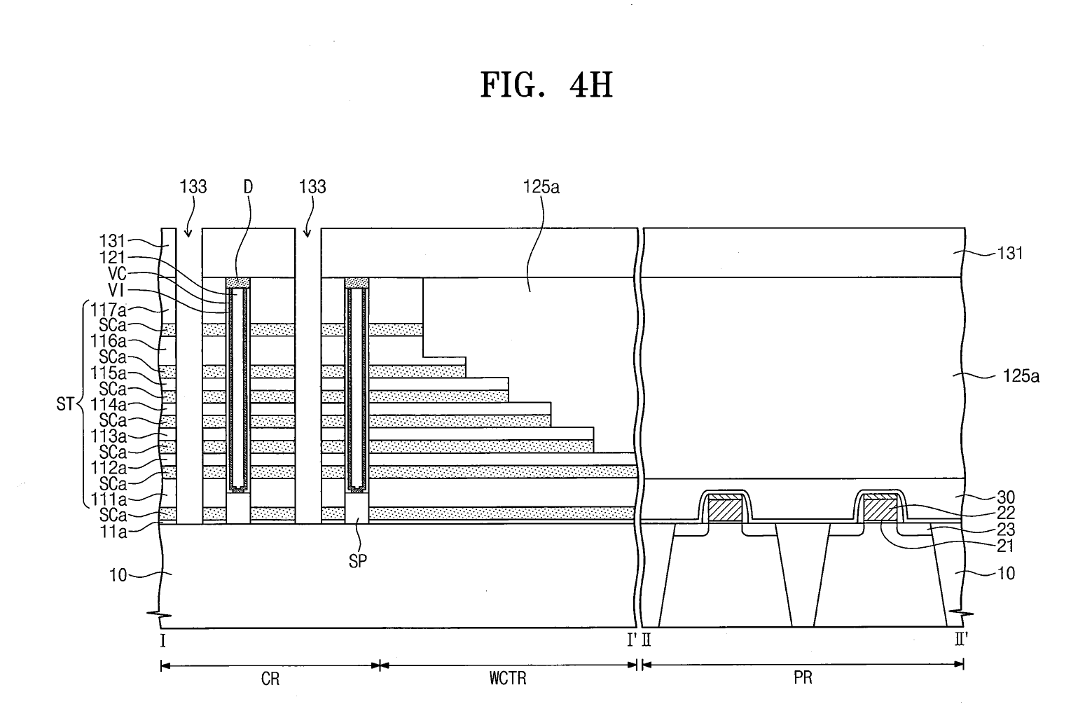

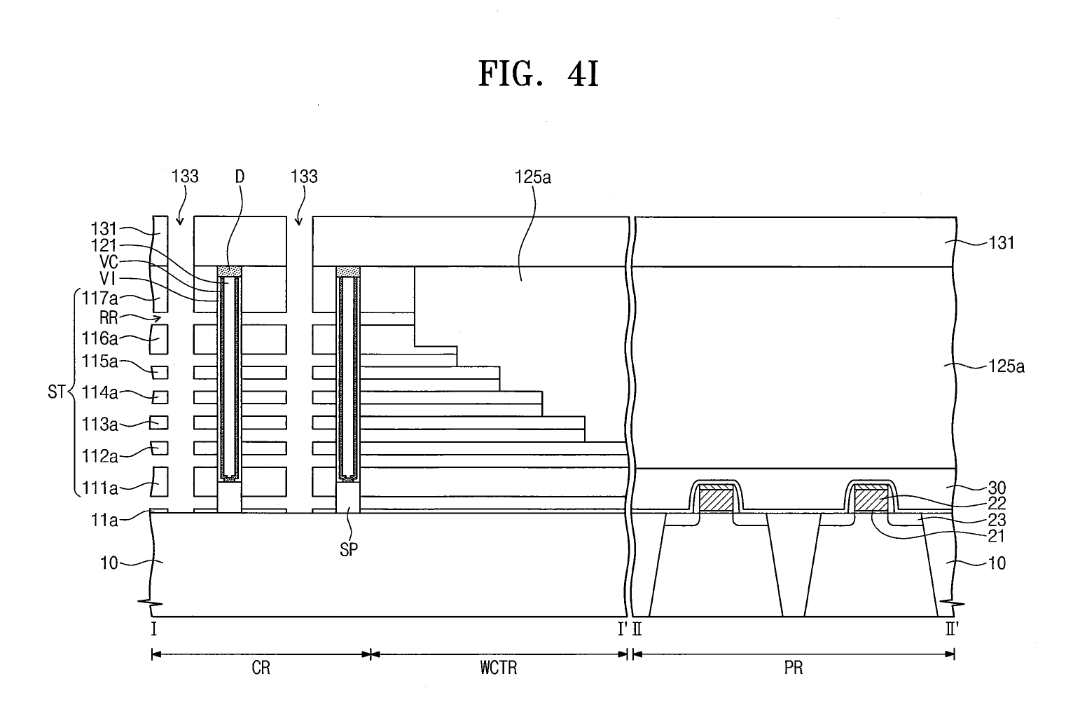

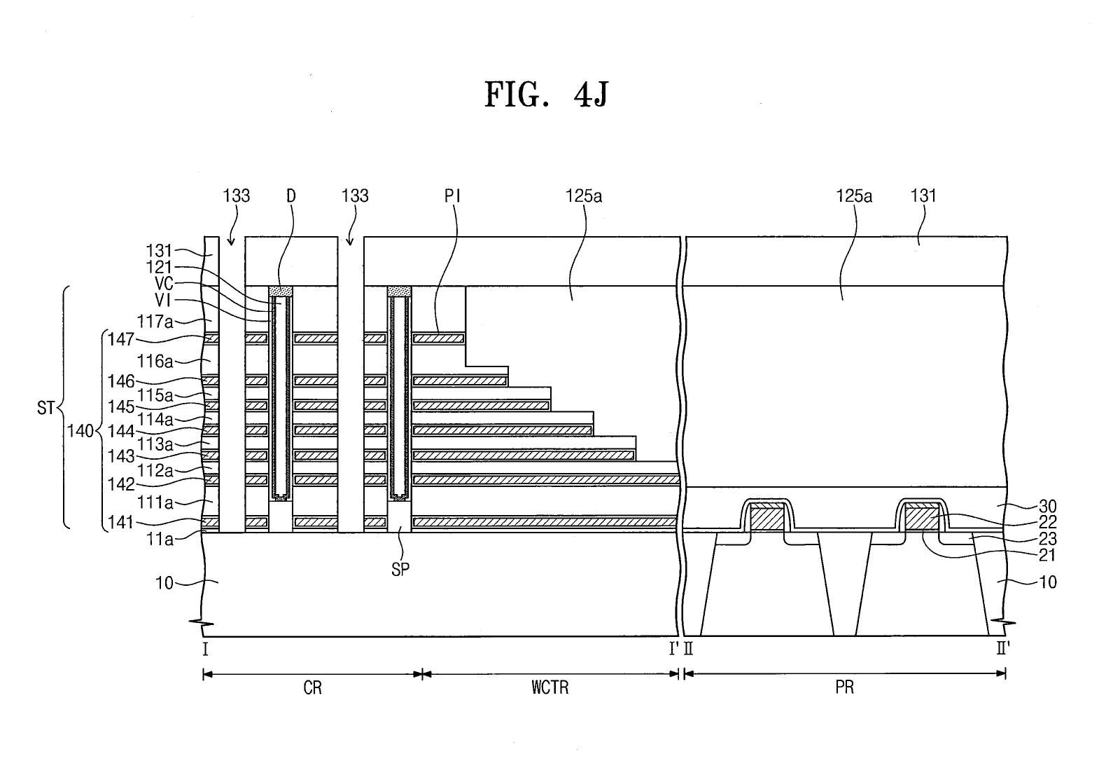

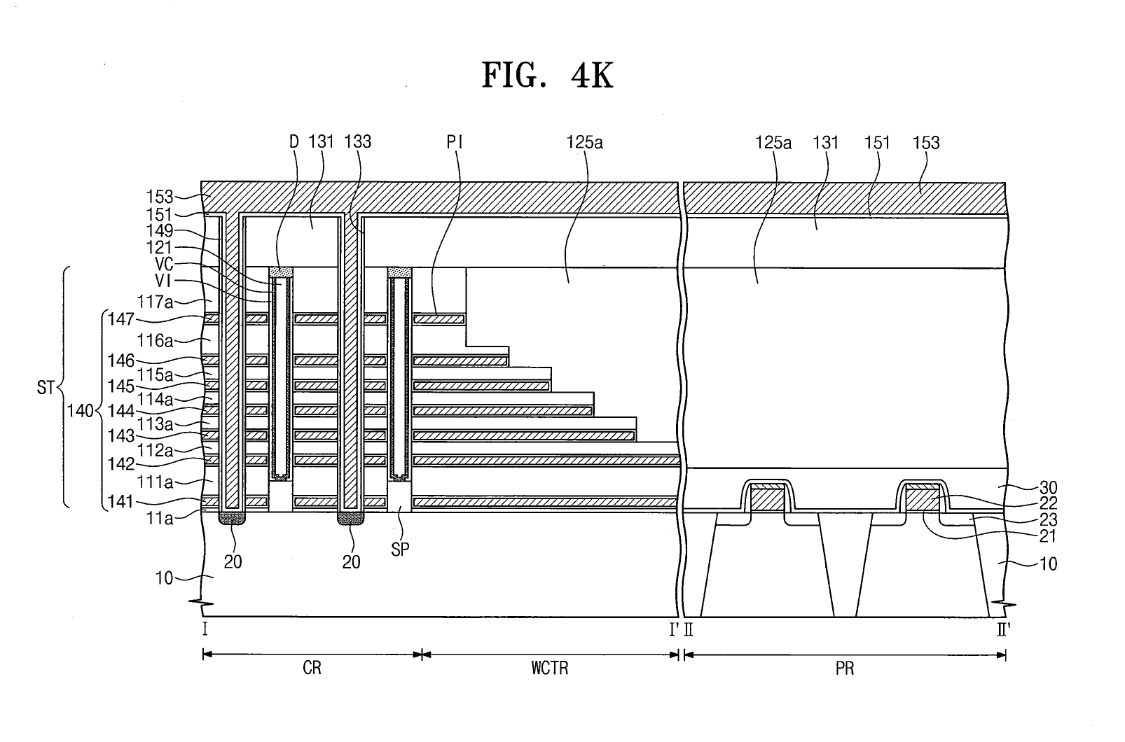

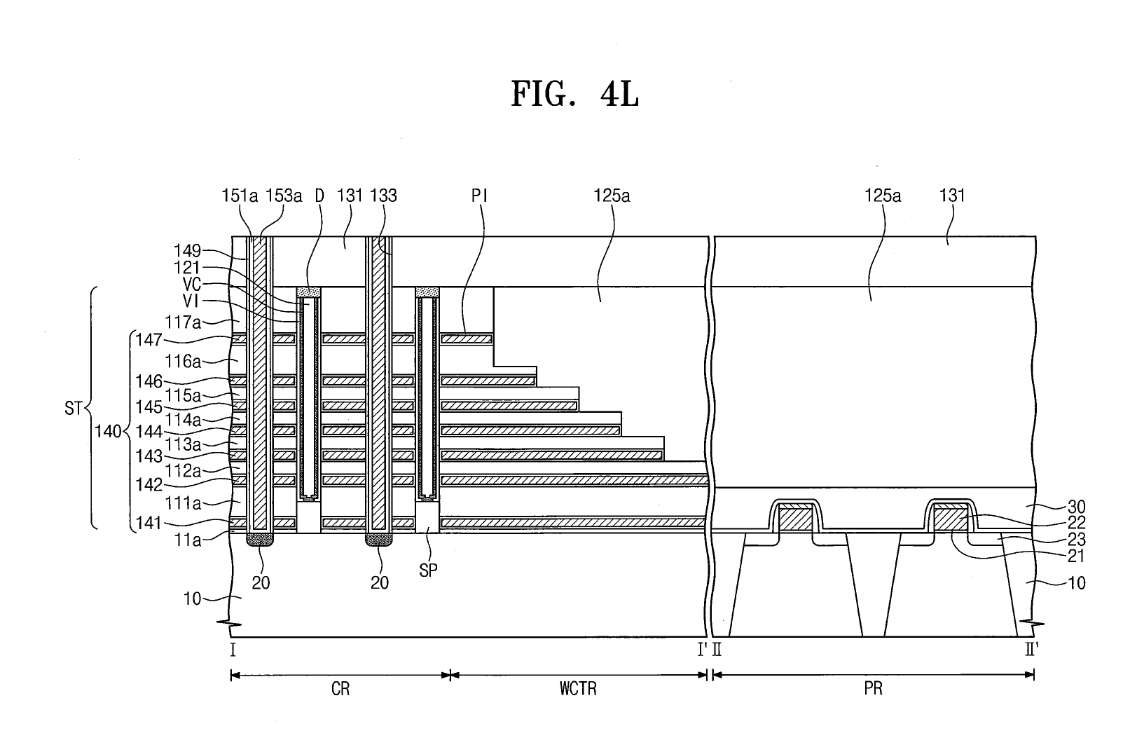

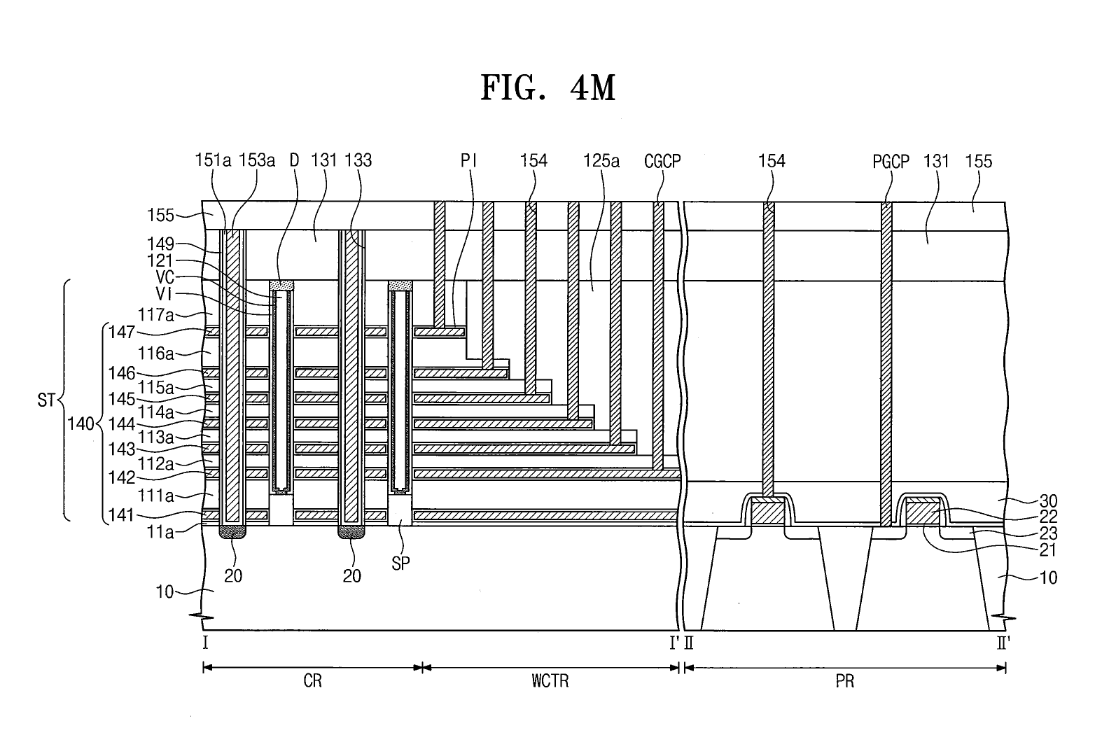

FIGS. 4A to 4M are cross-sections taken along lines I-I′ and II-II′ of FIG. 1 illustrating processing steps in the fabrication of semiconductor memory devices according to some embodiments of the inventive concept. Referring first to FIG. 4A, a substrate 10 may include a cell array region CR, a contact region WCTR, and a peripheral circuit region PR. A device isolation layer may be formed in the substrate 10 to define active regions. Peripheral circuits for writing and sensing memory cells may be formed on the substrate 10 of the peripheral circuit region PR.

For example, the peripheral circuits may include a word line driver, a sense amplifier, row and column decoders, and control circuits. In some embodiments, peripheral transistors included in the peripheral circuits may be formed on the substrate 10 of the peripheral circuit region PR, as illustrated in FIG. 4A. The substrate 10 may be, for example, a silicon substrate, a silicon-germanium substrate, a germanium substrate, or a single-crystalline epitaxial layer grown on a single-crystalline silicon substrate.

In some embodiments, the peripheral transistors may be formed by the following processes. A peripheral gate insulating layer and a peripheral gate layer may be sequentially formed on an entire top surface of the substrate 10. The peripheral gate insulating layer may be used as gate insulating layers of the peripheral transistors and may be formed of a silicon oxide layer formed by a thermal oxidation process. The peripheral gate layer and the peripheral gate insulating layer may be successively patterned to form a peripheral gate insulating pattern 21 and a peripheral gate pattern 22 which are sequentially stacked on the substrate 10. The peripheral gate pattern 22 may be used as a gate electrode of the peripheral transistor included in the peripheral circuits. The peripheral gate pattern 22 may be formed of at least one of poly-silicon doped with dopants or a metal material. Peripheral dopant regions 23 may be formed in the active region at both sides of the peripheral gate pattern 22. The peripheral dopant regions 23 may be used as source and drain regions of the peripheral transistor. Meanwhile, a lower gate insulating layer 11 may not be patterned when the peripheral gate pattern 22 is formed. The lower gate insulating layer 11 may cover a top surface of the substrate 10 of the cell array region CR.

Subsequently, a peripheral insulating pattern 30 may be formed on the substrate 10 having the peripheral transistors. The peripheral insulating pattern 30 may be formed of a silicon oxide layer. The peripheral circuits of the peripheral circuit region PR may be buried in the peripheral insulating pattern 30.

An insulating layer may be deposited on an entire top surface of the substrate 10 after the formation of the peripheral circuits, and then, the insulating layer of the cell array region CR and the contact region WCTR may be removed to form the peripheral insulating pattern 30. In other words, the peripheral insulating pattern 30 may be locally formed on the substrate 10 of the peripheral circuit region PR but may not be formed on the substrate 10 of the cell array region CR and the contact region WCTR.

Furthermore, a peripheral etch stop layer 32 may be formed on the peripheral insulating pattern 30, as illustrated in FIG. 4A. The peripheral etch stop layer 32 may be formed of a material, such as silicon nitride, having an etch selectivity with respect to the peripheral insulating pattern 30.

A stack structure ST may be formed on an entire top surface of the substrate 10 having the peripheral insulating pattern 30. In other words, the stack structure ST may be formed on the substrate 10 of the cell array region CR, a contact region WCTR and a peripheral circuit region PR. The stack structure ST may include sacrificial layers SC and insulating layers 111 to 117. The sacrificial layers SC and the insulating layers 111 to 117 may be alternately and repeatedly stacked on the substrate 10. The sacrificial layers SC may include a material having an etch selectivity with respect to the insulating layers 111 to 116. For example, the sacrificial layers SC may be formed of, for example, silicon nitride layers, and the insulating layers 111 to 117 may be formed of, for example, silicon oxide layers.

Referring now to FIG. 4B, the stack structure ST of the cell array region CR may be patterned to form channel holes 120. In particular, a mask pattern (not shown) may be formed to cover an entire portion of the stack structure ST of the contact region WTCR and the peripheral circuit region PR and a portion of the stack structure of the cell array region CR, and then, the insulating layers 111 to 117 and the sacrificial layers SC may be etched using the mask pattern as an etch mask to form the channel holes 120. The etching process for the formation of the channel holes 120 may be performed until a top surface of the substrate 10 is exposed. Even though not shown in the drawings, the top surface of the substrate 10 under the channel holes 120 may be recessed by over-etching.

Referring to FIG. 4C, a semiconductor pillar SP may be formed on the substrate 10 exposed through each of the channel holes 120. In particular, the semiconductor pillar SP may be grown from the substrate 10 by performing a SEG process using the substrate 10 exposed through the channel hole 120 as a seed. For example, the semiconductor pillar SP may be formed of an intrinsic semiconductor or a semiconductor doped with P-type dopants.

A vertical insulating layer VI may be formed to conformally cover a sidewall of each of the channel holes 120 and a portion of a top surface of the semiconductor pillar SP. For example, the vertical insulating layer VI may be formed using a chemical vapor deposition (CVD) process and/or an atomic layer deposition (ALD) process. The vertical insulating layer VI may be formed of a single layer or a multi-layer. For example, the vertical insulating layer VI may include at least one of thin layers, for example, a tunnel insulating layer, a trap insulating layer, and a blocking insulating layer, used as a memory element of a charge trap-type non-volatile memory transistor. For example, the vertical insulating layer VI may include at least one of a silicon oxide layer, a silicon nitride layer, or a silicon oxynitride layer.

A vertical channel part VC may be formed to conformally cover a sidewall of the vertical insulating layer VI and the top surface of the semiconductor pillar SP in each of the channel holes 120. For example, the vertical channel part VC may be formed using a CVD process and/or an ALD process. The vertical channel part VC may include at least one of a poly-crystalline silicon layer, an organic semiconductor layer, or a carbon nano structure.

A hydrogen annealing process may be performed on the vertical channel parts VC in a gas atmosphere including hydrogen or heavy hydrogen after the formation of the vertical channel parts VC. Crystal defects existing in the vertical channel parts VC may be cured by the hydrogen annealing process.

An insulating pillar 121 may be formed to fill the channel hole 120 having the vertical channel part VC. For example, the insulating pillar 121 may be formed using a spin-on-glass (SOG) process. The insulating pillar 121 may include an insulating material, for example, silicon oxide or silicon nitride.

A conductive pad D may be formed in a top end portion of the vertical channel part VC. The vertical insulating layer VI and the insulating pillar 121 may be disposed under the conductive pad D. In some embodiments, the vertical insulating layer VI, the vertical channel part VC, and the insulating pillar 121 may be recessed, and then, the recessed region may be filled with a conductive material, thereby forming the conductive pad D. In some embodiments, the conductive pad D may be formed by doping top end portions of the vertical insulating layer VI, the vertical channel part VC, and the insulating pillar 121 with dopants of which a conductivity type is different from that of the vertical channel part VC.

Referring now to FIG. 4D, a mask pattern 123 may be formed on the stack structure ST of the cell array region CR of the substrate 10. The sacrificial layers SC and the insulating layers 111 to 117 exposed by the mask pattern 123 may be etched, and thus, the stack structure ST of the contact region WCTR may be formed into a stepped structure.

A process of reducing a planar area of the mask pattern 123 and a process of reducing etch-amounts of the insulating layers 111 to 117 and the sacrificial layers SC may be repeatedly performed to form the stepped structure of the stack structure 20.

In particular, an initial mask pattern 123 may be formed on the substrate 10 of the cell array region CR and a portion of the contact region WCTR to expose an entire portion of the uppermost insulating layer 117 of the peripheral circuit region PR and a portion of the uppermost insulating layer 117 of the contact region WCTR. A first etching process may be performed on the stack structure ST using the initial mask pattern 123 as an etch mask, thereby removing an entire portion of the insulating layers 111 to 117 and the sacrificial layers SC of the peripheral circuit region PR and an entire portion of the insulating layers 111 to 117 and the sacrificial layers SC of the portion, exposed by the mask pattern 123, of the contact region WCTR. Thus, the peripheral insulating pattern 30 of the peripheral circuit region PR may be exposed, and a top surface of a portion of the substrate 10 of the contact region WCTR may be exposed.

A planar area of the mask pattern 123 may be reduced, and a second etching process may be performed on the insulating layers 111 to 117 and the sacrificial layers SC of the contact region WCTR exposed by the mask pattern 123 having the reduced area. At this time, etched amounts of the insulating layers 111 to 117 and the sacrificial layers SC by the second etching process may be less than etched amounts of the insulating layers 111 to 117 and the sacrificial layers SC by the first etching process. For example, the insulating layers 112 and 117 and the sacrificial layers SC stacked on the lowermost insulating layer 111 may be etched by the second etching process to expose the lowermost insulating layer 111. In other words, the lowermost insulating layer 111 and the lowermost sacrificial layer SC may remain immediately after the second etching process.

After the process of reducing the planar area of the mask pattern 123 and the process of reducing the etch-amounts of the insulating layers 111 to 117 and the sacrificial layers SC are repeatedly performed, a final mask pattern 123 may remain on the stack structure ST of only the cell array region CR. Furthermore, end portions of the sacrificial layers SC and the insulating layers 111 to 117 respectively covering the sacrificial layers SC may be disposed at positions horizontally different from each other. In other words, planar areas of the sacrificial layers SC and the insulating layers 111 to 117 may be sequentially decreased as a distance from the substrate 10 is increased.

The mask pattern 123 may be removed after the formation of the stepped structure. Meanwhile, a height difference may occur between the stack structure of the cell array region CR and the contact region WCTR and the structure of the peripheral circuit region PR. For example, the top surface of the uppermost insulating layer 117 of the stack structure ST of the cell array region CR may be disposed at a different level from the top surface of the peripheral insulating pattern 30 of the peripheral circuit region PR.

Referring to FIG. 4E, an interlayer insulating layer 125 may be formed on an entire top surface of the substrate 10. The interlayer insulating layer 125 may be formed on the stack structure ST of the cell array region CR and the contact region WCTR and the structure of the peripheral circuit region PR. A top surface of the interlayer insulating layer 125 may have a height difference by the height difference between the structures of the substrate 10. For example, the top surface of the interlayer insulating layer 125 of the cell array region CR may be higher than top surfaces of the interlayer insulating layer 125 of the contact region WCTR and the peripheral circuit region PR, and the top surface of the interlayer insulating layer 125 of the peripheral circuit region PR may be disposed at the lowermost level. The top surface of the interlayer insulating layer 125 of the contact region WCTR may have an inclined surface that becomes progressively lower from the cell array region CR to the peripheral circuit region PR.

The interlayer insulating layer 125 may be formed using, for example, a physical vapor deposition (PVD) process, a CVD process, a sub-atmospheric chemical vapor deposition (SACVD) process, a low-pressure chemical vapor deposition (LPCVD) process, a plasma-enhanced chemical vapor deposition (PECVD) process, or a high-density plasma chemical vapor deposition (HDP CVD) process.

The interlayer insulating layer 125 may be formed of a material having an etch selectivity with respect to the sacrificial layers SC in a subsequent process of removing the sacrificial layers SC. For example, the interlayer insulating layer 125 may be formed of at least one of a HDP oxide layer, tetraethylorthosilicate (TEOS), plasma-enhanced tetraethylorthosilicate (PE-TEOS), O₃-tetra ethyl ortho silicate (O₃-TEOS), undoped silicate glass (USG), phosphosilicate glass (PSG), borosilicate glass (BSG), borophosphosilicate glass (BPSG), fluoride silicate glass (FSG), spin-on-glass (SOG), or Tonen silazene (TOSZ). Other example, the interlayer insulating layer 125 may include silicon nitride, silicon oxynitride, or a low-k dielectric material having a low dielectric constant.

A polishing stop layer 127 may be formed on the interlayer insulating layer 125. The polishing stop layer 127 may be a sacrificial layer that reduces the likelihood of, or possibly prevents, a dishing phenomenon from occurring in the contact region WCTR and the peripheral circuit region PR during a chemical mechanical polishing (CMP) process of the interlayer insulating layer 125.

For example, the polishing stop layer 127 may be formed using a deposition process such as a CVD process, a PVD process, or an ALD process. The polishing stop layer 127 may be formed of a material of which a removal rate is lower than that of the interlayer insulating layer 125. For example, the polishing stop layer 127 may be formed of at least one selected from a group consisting of silicon nitride (SiN), silicon oxynitride (SiON), silicon carbide (SiC), silicon oxy-carbide (SiOC), a conductive layer, SiLK, black diamond, CORAL, BN, and an anti-reflective coating (ARC) layer.

Referring now to FIG. 4F, a portion of the interlayer insulating layer 125 of the cell array region CR may be removed to reduce the height difference between the interlayer insulating layer 125 of the cell array region CR and the interlayer insulating layer 125 of the contact region WCTR. In particular, a photoresist pattern (not shown) may be formed to expose the polishing stop layer 127 of the cell array region CR, and then, the polishing stop layer 127 and the interlayer insulating layer 125 may be etched using the photoresist pattern as an etch mask. Thus, an upper portion of the interlayer insulating layer 125 of the contact region WCTR may protrude from the interlayer insulating layer 125 of the cell array region CR and the peripheral circuit region PR.

Referring now to FIG. 4G, a planarization process may be performed on the interlayer insulating layer 125 to form an interlayer insulating pattern 125a. The planarization process may be performed until the top surface of the conductive pad D of the cell array region CR is exposed. The interlayer insulating pattern 125a may be formed on the substrate 10 of the contact region WCTR and the peripheral circuit region PR.

During the planarization process, the polishing stop layer 127 of the contact region WCTR may be removed to expose a top surface of the interlayer insulating pattern 125a but the polishing stop layer 127 of the peripheral circuit region PR may remain. On the other hand, since the polishing stop layer 127 of the contact region WCTR is removed prior to the interlayer insulating layer 125, a top surface of a portion of the interlayer insulating pattern 125a of the contact region WCTR may be lower than the top surface of the uppermost insulating pattern 117a.

After the planarization process, the polishing stop layer 127 of the peripheral circuit region PR may be selectively removed.

Referring now to FIG. 4H, a first separation insulating layer 131 exposing portions of the stack structure ST of the cell array region CR may be formed on the substrate 10, and the exposed stack structure ST may be etched using the first separation insulating layer 131 as an etch mask to form common source trenches 133. As illustrated in FIG. 1, the common source trenches 133 may have linear shapes extending in the one direction D3 when viewed from a plan view. The common source trenches 133 are formed, so a gate insulating pattern 11a, sacrificial patterns SCa, and insulating patterns 111a to 117a may be formed on the substrate 10. The etching process for the formation of the common source trenches 133 may be an anisotropic etching process.

Sidewalls of the sacrificial patterns SCa may be exposed at sidewalls of the common source trenches 133. The process of forming the common source trenches 133 may be a process of exposing the sacrificial patterns SCa for performing a selective etching process selectively removing only the sacrificial patterns SCa. The first separation insulating layer 131 may be formed of a material having an etch selectivity with respect to the sacrificial patterns SCa. For example, the first separation insulating layer 131 may include a silicon oxide layer.

Referring now to FIG. 41, the sacrificial patterns SCa exposed through the common source trenches 133 may be selectively removed to form recess regions RR. In particular, the recess regions RR may be disposed between the insulating patterns 111a to 117a vertically stacked. Since the sacrificial patterns SCa include the material having an etch selectivity with respect to the insulating patterns 111a to 117a, the insulating patterns 111a to 117a may not be removed when the sacrificial patterns SCa are removed. The selective etching process may include a wet etching process and/or a dry etching process. For example, if the sacrificial patterns SCa are formed of silicon nitride and the insulating patterns 111a to 117a are formed of silicon oxide, the selective etching process may be performed using an etching solution including phosphoric acid.

The recess regions RR may expose top and bottom surfaces of the insulating patterns 111a to 117a, portions of an outer sidewall of the vertical insulating layer VI, and a portion of a sidewall of the semiconductor pillar SP. The recess regions RR may be gap regions that horizontally extend from the common source trenches 133 into between the insulating patterns 111a to 117a.

Referring now to FIGS. 4J, a horizontal insulating layer PI may be formed to cover inner surfaces of the recess regions RR. In particular, the horizontal insulating layer PI may conformally cover the top and bottom surfaces of the insulating patterns 111a to 117a, the portions of the outer sidewall of the vertical insulating layer VI, and the portion of the sidewall of the semiconductor pillar SP, which are exposed through the recess regions RR.

Similar to the vertical insulating layer VI, the horizontal insulating layer PI may be formed of a single layer or a multi-layer. The horizontal insulating layer PI may correspond to the blocking insulating layer of the charge trap-type non-volatile memory transistor. In these embodiments, the horizontal insulating layer PI may be a silicon oxide layer. Alternatively, the horizontal insulating layer PI may further include the trap insulating layer, or the trap insulating layer and the tunnel insulating layer. The horizontal insulating layer PI may be formed using a deposition process with an excellent step coverage characteristic. For example, the horizontal insulating layer PI may be formed using a CVD process or an ALD process.

Gate electrodes 140 may be formed by filling the recess regions RR with a conductive material. Forming the gate electrodes 140 may include forming a conductive layer filling the recess regions RR, and removing the conductive layer formed in the common source trenches 133 to confinedly leave portions of the conductive layer in the recess regions RR. In some embodiments, the conductive layer may be formed to fill the common source trenches 133. In these embodiments, the conductive layer in the common source trenches 133 may be anisotropically etched.

Even though not shown in the drawings, when the gate electrodes 140 are formed in the recess regions RR, the gate electrodes 140 may be over-etched. Thus, sidewalls of the gate electrodes 140 exposed by the common source trenches 133 may be laterally recessed from sidewalls of the insulating patterns 111a to 1117a exposed by the common source trenches 133. In other words, the sidewalls of the gate electrodes 140 may be formed in the recess regions RR. The gate electrodes 140 may include a conductive material. For example, the gate electrodes 140 may include at least one of doped silicon, a metal such as tungsten, copper, or aluminum, a conductive metal nitride such as titanium nitride or tantalum nitride, or a transition metal such as titanium or tantalum.

Referring now to FIG. 4K, dopant regions 20 may be formed in the substrate 10 exposed by the common source trenches 133. The dopant regions 20 may be formed using an ion implantation process and may be formed in the substrate 10 through the common source trenches 133. A conductivity type of the dopant regions 20 may be different from that of the substrate 10.

Spacers 149 may be formed on the sidewalls of the common source trenches 133. The spacers 149 may electrically insulate the gate electrodes 140 from common source plugs 153a to be formed in a subsequent process. The spacers 149 may include an insulating material, for example, silicon oxide.

A barrier layer 151 and a conductive layer 153 may be formed in the common source trenches 133. In particular, the barrier layer 151 may be conformally formed on the sidewalls and bottom surfaces of the common source trenches 133 and a top surface of the first separation insulating layer 131 of the contact and peripheral circuit regions WCTR and PR. The conductive layer 153 may be formed on the barrier layer 151 to fill the common source trenches 133 and to cover the first separation insulating layer 131. For example, the barrier layer 151 may be formed by a CVD process or an ALD process. For example, the conductive layer 153 may be formed by a CVD process, a PVD process, or an ALD process. The barrier layer 151 may be formed of, but not limited to, a metal nitride such as titanium nitride or tantalum nitride. The conductive layer 153 may be formed of, but not limited to, a metal such as tungsten, copper, or aluminum and/or a transition metal such as titanium or tantalum.

Referring now to FIG. 4L, the conductive layer 153 and the barrier layer 151 may be etched until the top surface of the first separation insulating layer 131 is exposed, thereby forming a barrier pattern 151a and a common source plug 153a in each of the common source trenches 133. The barrier pattern 151a may have a U-shaped cross-section. The common source plug 153a may be electrically connected to the dopant region 20. The etching process of the conductive layer 153 and the barrier layer 151 may be performed using a CMP process or an etch-back process. A top surface of the common source plug 153a may be higher than the top surface of the vertical channel part VC.

If the first separation insulating layer 131 is removed in the etching process for forming the common source plug 153a, a top surface of the common source plug 153a may be disposed at the substantially same level as the top surface of the vertical channel part VC. However, if the first separation insulating layer 131 is removed, the conductive pad D may be exposed. In these embodiments, the conductive pad D may be damaged by impurities of the etched conductive layer 153. Thus, electrical characteristics of the gate electrodes 140 may be deteriorated. However, according to some embodiments of the inventive concept, the first separation insulating layer 131 is not removed to reduce the likelihood, or possibly prevent, the above problem.

Referring now to FIG. 4M, a second separation insulating layer 155 may be formed on the first separation insulating layer 131. The second and first separation insulating layers 155 and 131, the interlayer insulating pattern 125a, insulating patterns 111a to 117a, and the horizontal insulating layer PI of the contact region WCTR may be successively patterned to form contact holes 154. At the same time, the second and first separation insulating layers 155 and 131, the interlayer insulating pattern 125a, and the peripheral insulating patterns 30 of the peripheral circuit region PR may be successively patterned to form contact holes 154. For example, the second separation insulating layer 155 may include an insulating material, for example, a silicon oxide layer, a silicon nitride layer, and/or a silicon oxynitride layer.

The contact holes 154 of the contact region WCTR may expose end portions of the gate electrodes 140, respectively. The contact holes 154 of the peripheral circuit region PR may expose the peripheral gate pattern 22 of a PMOS transistor and the peripheral dopant region 23 of a NMOS transistor, respectively.

The gate electrodes 140 of the contact region WCTR and the peripheral gate pattern 220 and the substrate 10 of the peripheral circuit region PR may be disposed at levels different from each other. For example, the contact hole 153 exposing the end portion of the uppermost gate electrode 147 may be formed prior to other contacts 154, and the contact hole 154 exposing the peripheral dopant region 23 may be finally formed after other contact holes 154 are formed. The contact holes 154 may be formed by an anisotropic etching process, for example, a dry etching process.

Meanwhile, since the gate electrodes 140 and the peripheral gate pattern 22 include materials having an etch selectivity with respect to etch target layers etched for forming the contact holes 154, they 140 and 22 may function as etch stop layers during the etching process. Thus, during the formation of the contact holes 154, the contact holes 154 formed in advance may not be further etched by the gate electrodes 140 and/or the peripheral gate pattern 22 until the last contact hole 153 is completely formed.

Cell contact plugs CGCP and peripheral contact plugs PGCP may be formed in the contact holes 154. A conductive layer (not shown) may be deposited to fill the contact holes 154, and then, the deposited conductive layer may be etched until a top surface of the second separation insulating layer 155 is exposed, thereby locally forming the cell contact plugs CGCP and the peripheral contact plugs PGCP in the contact holes 154. Top surfaces of the cell and peripheral contact plugs CGCP and PGCP may be higher than the top surface of the common source plug 153a and the top surface of the vertical channel part VC. The cell and peripheral contact plugs CGCP and PGCP may include a metal layer such as tungsten and a metal barrier layer such as a metal nitride. The etching process for forming the cell and peripheral contact plugs CGCP and PGCP may be, for example, an etch-back process or a CMP process.

In some embodiments, the cell and peripheral contact plugs CGCP and PGCP may be formed after the formation of the common source plug 153a. If the cell and peripheral contact plugs CGCP and PGCP are formed before the formation of the common source plug 153a, the etching process for forming the contact holes 154 may be performed before the formation of the gate electrodes 140. Thus, the etching process may be performed without an etch stop layer. In these embodiments, it may be difficult to form contact holes 154 having heights different from each other at once. However, according to the above embodiments of the inventive concept, the cell and peripheral contact plugs CGCP and PGCP are formed after the formation of the common source plug 153a to solve the above mentioned problem. As a result, the top surfaces of the cell and peripheral contact plugs CGCP and PGCP are higher than the top surface of the common source plug 153a.

Referring again to FIG. 2, contact pads 159 may be formed on the second separation insulating layer 155. The contact pads 159 may be disposed on the cell and peripheral contact plugs CGCP and PGCP, respectively. An additional separation insulating layer 160 may be formed on the second separation insulating layer 155. The additional separation insulating layer 160 may cover the contact pads 159. For example, the additional separation insulating layer 160 may include at least one of a silicon oxide layer, a silicon nitride layer, or a silicon oxynitride layer.

Bit line contact plugs BLCP, first contacts MC1, and second contacts MC2 may be formed in the cell array region CR, the contact region WCTR, and the peripheral circuit region PR, respectively. The bit line contact plug BLCP may penetrate the additional, second and first separation insulating layers 160, 155 and 131 of the cell array region CR so as to be connected to the conductive pad D. The first contacts MCI may penetrate the additional separation insulating layer 160 of the contact region WCTR so as to be connected to the contact pads 159 of the contact region WCTR, respectively. The second contacts MC2 may penetrate the additional separation insulating layer 160 of the peripheral circuit region PR so as to be connected to the contact pads 159 of the peripheral circuit region PR, respectively.

Bit lines BL may be formed on the additional separation insulating layer 160 of the cell array region CR, and global word lines GWL may be formed on the additional separation insulating layer 160 of the contact region WCTR and the peripheral circuit region PR. The bit lines BL may be connected to the bit line contact plugs BLCP, and the global word lines GWL may be connected to the first contacts MC1 and the second contacts MC2. For example, the bit lines BL and the global word lines GWL may include at least one of a metal such as tungsten, copper, or aluminum, a conductive metal nitride such as titanium nitride or tantalum nitride, or a transition metal such as titanium or tantalum.

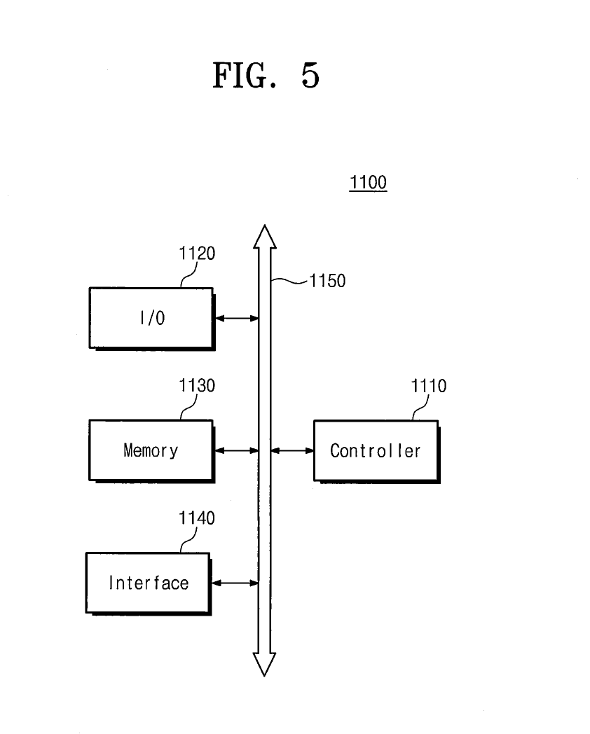

Referring now to FIG. 5, a schematic block diagram illustrating an example of an electronic system including a semiconductor memory device according to embodiments of the inventive concept will be discussed. As illustrated in FIG. 5, an electronic system 1100 according to embodiments of the inventive concept may include a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150. The data bus 1150 may correspond to a path through which electrical signals are transmitted. The memory device 1130 may include at least one of the semiconductor memory devices according to the aforementioned embodiments of the inventive concept.

The controller 1110 may include at least one of a microprocessor, a digital signal processor, a microcontroller, or other logic devices having a similar function to any one thereof. The I/O unit 1120 may include a keypad, a keyboard and/or a display device. The memory device 1130 may store data and/or commands. The interface unit 1140 may transmit electrical data to a communication network or may receive electrical data from a communication network. The interface unit 1140 may operate by wireless or cable. For example, the interface unit 1140 may include an antenna or a cable/wireless transceiver. Although not shown in the drawings, the electronic system 1100 may further include a fast dynamic random access memory (DRAM) device and/or a fast static random access memory (SRAM) device which acts as a cache memory for improving an operation of the controller 1110.

The electronic system 1100 may be applied to a personal digital assistant (PDA), a portable computer, a web tablet, a wireless phone, a mobile phone, a digital music player, or other electronic products receiving and/or transmitting information data by wireless.

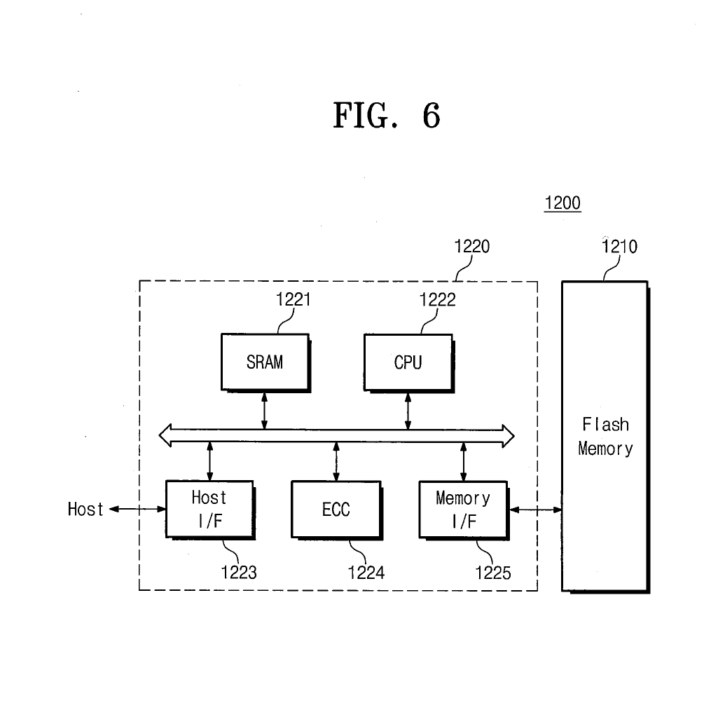

Referring now to FIG. 6, a schematic block diagram illustrating an example of a memory system including a semiconductor memory device according to embodiments of the inventive concept will be discussed. As illustrated in FIG. 6, a memory system 1200 may include a memory device 1210. The memory device 1210 may include at least one of the semiconductor memory devices according to the embodiments mentioned above. Furthermore, the memory device 1210 may further include another type of a semiconductor memory device. For example, the memory device 1210 may further include a DRAM device and/or a SRAM device. The memory system 1200 may include a memory controller 1220 that controls data communication between a host and the memory device 1210.

The memory controller 1220 may include a central processing unit (CPU) 1222 that controls overall operations of the memory system 1200. Furthermore, the memory controller 1220 may include an SRAM device 1221 used as a working memory of the CPU 1222. Moreover, the memory controller 1220 may further include a host interface unit 1223 and a memory interface unit 1225. The host interface unit 1223 may be configured to include a data communication protocol between the memory system 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. Even though not shown in the drawings, the memory system 1200 may further include a read only memory (ROM) device that stores code data to interface with the host. The memory system 1200 may be used as a portable data storage card such as a memory card. Alternatively, the memory card 1200 may be realized as solid state disks (SSD) which are used as hard disks of computer systems.

In semiconductor memory devices according to some embodiments of the inventive concept, the top surface of the vertical channel part, the top surface of the common source plug, and the top surfaces of the cell and peripheral contact plugs may be disposed at levels different from each other, so the reliability of the semiconductor memory device may be improved.

While the inventive concept have been described with reference to example embodiments, it will be apparent to those skilled in the art that various changes and modifications may be made without departing from the spirits and scopes of the inventive concept. Therefore, it should be understood that the above embodiments are not limiting, but illustrative. Thus, the scopes of the inventive concept are to be determined by the broadest permissible interpretation of the following claims and their equivalents, and shall not be restricted or limited by the foregoing description.

What is claimed is:

1. A semiconductor memory device comprising:
a substrate;
a stack structure including gate electrodes vertically stacked on the substrate;
a vertical channel part penetrating the gate electrodes;
a dopant region in the substrate at a side of the stack structure;
a common source plug on the substrate, the common source plug electrically connected to the dopant region; and
cell contact plugs connected to the gate electrodes, respectively,
wherein a top surface of the common source plug is at a different level from top surfaces of the cell contact plugs.

2. The device of claim 1, wherein the top surfaces of the cell contact plugs are at a higher level than the top surface of the common source plug.

3. The device of claim 1, further comprising:
a first separation insulating layer and a second separation insulating layer sequentially stacked on the stack structure,
wherein the common source plug extends upward to penetrate the first separation insulating layer;
wherein the top surface of the common source plug is disposed at substantially the same level as a top surface of the first separation insulating layer;
wherein the cell contact plugs extend upward to penetrate the first and second separation insulating layers; and
wherein the top surfaces of the cell contact plugs are disposed at the substantially same level as a top surface of the second separation insulating layer.

4. The device of claim 3, wherein the second separation insulating layer extends onto the common source plug to cover the top surface of the common source plug.

5. The device of claim 1, wherein a top surface of the vertical channel part is lower than the top surface of the common source plug and the top surfaces of the cell contact plugs.

6. The device of claim 1, wherein the substrate comprises:
a cell array region including the vertical channel part;
a contact region including the cell contact plugs; and
a peripheral circuit region, the semiconductor memory device further comprising:
a peripheral gate pattern on the substrate of the peripheral circuit region;
a peripheral dopant region in the substrate at a side of the peripheral gate pattern; and
peripheral contact plugs on the substrate of the peripheral circuit region, the peripheral contact plugs electrically connected to the peripheral gate pattern and the peripheral dopant region.

7. The device of claim 6, wherein top surfaces of the peripheral contact plugs are at substantially the same level as the top surfaces of the cell contact plugs.

8. The device of claim 6, wherein top surfaces of the peripheral contact plugs are disposed at a different level from the top surfaces of the cell contact plugs.

9. The device of claim 8, wherein the top surfaces of the peripheral contact plugs are at a higher level than the top surfaces of the cell contact plugs.

10. A semiconductor memory device comprising:
a substrate including a cell array region and a contact region;
a stack structure including gate electrodes vertically stacked on the substrate;
a vertical channel part penetrating the gate electrodes on the substrate of the cell array region;
a dopant region in the substrate at a side of the stack structure;
a common source plug on the substrate, the common source plug electrically connected to the dopant region; and
cell contact plugs respectively connected to the gate electrodes on the substrate of the contact region,
wherein a top surface of the vertical channel part, a top surface of the common source plug, and a top surface of each of the cell contact plugs are at levels different from each other.

11. The device of claim 10, wherein the top surface of the vertical channel part is at a lower level than the top surface of the common source plug.

12. The device of claim 10, wherein the top surface of the vertical channel part is at a lower level than the top surfaces of the cell contact plugs.

13. The device of claim 10, wherein the top surface of the vertical channel part is at a lower level than the top surface of the common source plug; and
wherein the top surface of the common source plug is at a lower level than the top surfaces of the cell contact plugs.

14. The device of claim 10:
wherein the substrate further comprises a peripheral circuit region; and
wherein the semiconductor memory device further comprises:
a peripheral gate pattern on the substrate of the peripheral circuit region;
a peripheral dopant region in the substrate at a side of the peripheral gate pattern; and
peripheral contact plugs on the substrate of the peripheral circuit region, the peripheral contact plugs electrically connected to the peripheral gate pattern and the peripheral dopant region.

15. The device of claim 14, wherein top surfaces of the peripheral contact plugs are disposed at substantially the same level as the top surfaces of the cell contact plugs.

16. A three-dimensional semiconductor memory device comprising:
a stack structure including gate electrodes vertically stacked on a substrate;
a vertical channel part penetrating the gate electrodes on the substrate in a cell array region thereof;
a dopant region in the substrate at a side of the stack structure;
a common source plug on the substrate, the common source plug electrically connected to the dopant region;
cell contact plugs respectively connected to the gate electrodes on the substrate in a contact region thereof;
a peripheral gate pattern on the substrate in a peripheral circuit region thereof;
a peripheral dopant region in the substrate at a side of the peripheral gate pattern; and
peripheral contact plugs on the substrate of the peripheral circuit region,
wherein a top surface of the vertical channel part, a top surface of the common source plug, a top surface of each of the cell contact plugs and peripheral contact plugs are at levels different from each other.

17. The device of claim 16, wherein the top surface of the vertical channel part is at a lower level than the top surface of the common source plug.

18. The device of claim 16, wherein the top surface of the vertical channel part is at a lower level than the top surfaces of the cell contact plugs.

19. The device of claim 16, wherein the top surface of the vertical channel part is at a lower level than the top surface of the common source plug; and
wherein the top surface of the common source plug is at a lower level than the top surfaces of the cell contact plugs.

20. The device of claim 19, wherein the top surfaces of the cell contact plugs are at a lower level than the top surfaces of the peripheral contact plugs.
